(19) United States
(12) Patent Application Publication
(10) Pub. No.: US 2017/0162609 A1
(43) Pub. Date: Jun. 8, 2017

(54) DISPLAY PANEL AND MANUFACTURING METHOD THEREOF

(71) Applicant: Innolux Corporation, Miao-Li County (TW)

(72) Inventors: Ker-Yih Kao, Miao-Li County (TW); Cheng-Hsu Chou, Miao-Li County (TW); Wang-Cheng Chung, Miao-Li County (TW)

(21) Appl. No.: 15/368,739

(22) Filed: Dec. 5, 2016

Related U.S. Application Data
(60) Provisional application No. 62/264,353, filed on Dec. 8, 2015.

(30) Foreign Application Priority Data
Apr. 21, 2016 (TW) 105112454

(51) Int. Cl. H01L 27/12; G02F 1/1341; G02F 1/1362; G02F 1/1343; H01L 29/786; G02F 1/1368

(52) U.S. Cl. CPC H01L 27/1262; H01L 27/1225; H01L 27/124; H01L 29/7869; G02F 1/1368; G02F 1/136286; G02F 1/13439; G02F 1/1341; G02F 2001/136295

(57) ABSTRACT

A display panel includes a first substrate, a second substrate and a display medium layer disposed between the first and second substrates. The first substrate includes a plurality of first conducive lines, a plurality of second conducive lines, and a plurality of transistors to define pixel regions. At least one of the transistors includes a gate electrode, a first insulating layer on the gate electrode, an active layer on the first insulating layer, a first electrode and a second electrode on the active layer. The first electrode includes a first transparent conductive material layer and a second transparent conductive material layer formed on the first transparent conductive material layer. The second conducive line connected to the first electrode includes the first and second transparent conductive material layers and a metal layer disposed between the first and second transparent conductive material layers.

This application claims the benefits of U.S. provisional application Ser. No. 62/264,353, filed Dec. 8, 2015, and Taiwan application Serial No. 105112454, filed Apr. 21, 2016, the subject matters of which are incorporated herein by reference.

### BACKGROUND OF THE INVENTION

Field of the Invention

The invention relates in general to a display panel and manufacturing method thereof, and more particularly to a transistor array substrate structure of a display panel and a manufacturing method thereof.

Description of the Related Art

Electronic products with display panel, such as smart phones, tablets, notebooks, monitors, and TVs, have become indispensable necessities to modern people no matter in their work, study or entertainment. Particularly, the liquid crystal display (LCD) panel having the advantages of lightweight, compactness, portability and low price is one of the most commonly used electronic products. The LCD panel has a diversified range of selection such as size, shape, and resolution.

Copper process is a most commonly used technology in the manufacturing process of a large-sized display panel. In the substrate of the display panel, semiconductor (formed of such as indium gallium zinc oxide (IGZO)), is generally used as the active layer of the thin-film transistor (such as IGZO TFT). Due to the high field effect mobility and feasibility in the large area process, semiconductor has great advantages when used in the large-size display. However, when the metal wires are formed of copper, due to the poor adhesion between copper and the underlying insulating film, an intermetallic layer (such as molybdenum) needs to be disposed between copper and the insulating layer to increase the adhesion between metal and the insulating layer. On the other hand, the intermetallic layer can be used as a diffusion blocking layer to avoid copper ions entering the active layer and decreasing element reliability. Examples of most commonly used compositions of the metal wires and the intermetallic layer include: copper/molybdenum (Cu/Mo), copper/titanium (Cu/Ti), and copper/molybdenum titanium alloy (Cu/Mo:Ti). When the IGZO layer is used as the active layer in transistors, metal (such as molybdenum or titanium) contacts IGZO and may easily bond with oxygen in IGZO and cause the conductivity of the active layer to change. Therefore, in the current process, after the second metal layer is defined (that is, after the source/drain is formed) but before the passivation layer (formed of such as silicon oxide (SiOx)) is deposited on the second metal layer, a surface treatment using nitrogen oxide (N₂O) plasma will be performed on the active layer to supplement the oxygen. However, such treatment will cause severe oxidation on the surface of the copper wires.

### SUMMARY OF THE INVENTION

According to one embodiment of the present invention, a display panel is provided. The display panel includes a first substrate, a second substrate disposed opposite to the first substrate, and a display medium layer disposed between the first substrate and the second substrate. The first substrate includes a plurality of first conductive lines, a plurality of second conductive lines intersected with the first conductive lines, and a plurality of transistors disposed over a base plate, wherein the first conductive lines, the second conductive lines and the transistors together define a plurality of pixel regions, and the first conductive lines extend along a first direction and the second conductive lines extend along a second direction. In the pixel regions, at least one of the transistors includes a gate electrode disposed over the base plate, a first insulating layer disposed over the gate electrode, an active layer disposed over the first insulating layer, and a first electrode and a second electrode disposed over the active layer and electrically connected to the active layer. The active layer includes a channel region disposed between the first electrode and the second electrode. The first electrode is composed of double layers of transparent conductive material including a first transparent conductive material layer disposed over the active layer and a second transparent conductive material layer disposed over the first transparent conductive material layer. In each pixel region, at least one of the second conductive lines is connected to the first electrode, and the at least one second conductive line includes a third transparent conductive material layer, a metal layer and a fourth transparent conductive material layer. The metal layer is disposed between the third transparent conductive material layer and the fourth transparent conductive material layer. In one embodiment, in each pixel region the first transparent conductive material layer and the second transparent conductive material layer of the first electrode extend to the corresponding metal layer of the second conductive line and encapsulate the metal layer to form the third transparent conductive material layer and the fourth transparent conductive material layer, respectively.

According to another embodiment of the present invention, a manufacturing method of a display panel is provided. The manufacturing method includes: forming a first substrate; providing a second substrate and further assembling the second substrate with the first substrate; providing a display medium layer between the first substrate and the second substrate. The step of forming the first substrate includes: forming a first metal layer on a base plate, patterning the first metal layer to form a plurality of first conductive lines and a plurality of gate electrodes, wherein the first conductive lines extend along a first direction and connect corresponding gate electrodes; forming a first insulating layer to cover the gate electrodes and the first conductive lines; forming a plurality of active layers on the first insulating layer; forming a first transparent conductive material layer on the first insulating layer; forming a plurality of metal layers on the first transparent conductive material layer; forming a second transparent conductive material layer on the metal layers and the first transparent conductive material layer; patterning the first transparent conductive material layer and the second transparent conductive material layer to form a plurality of second conductive lines extending along a second direction, a plurality of first electrodes, and a plurality of second electrodes on the base plate, wherein each second conductive line comprises a first transparent conductive layer formed of the first transparent conductive material layer, the metal layer, and a second transparent conductive layer formed of the second transparent conductive material layer, and the second conductive lines are intersected with the first conductive lines to define a plurality of pixel region; wherein, in each pixel region, the first electrode and the second electrode are disposed over the active layer, the channel region is disposed between the first electrode and the second electrode, and the first electrode is formed of the first transparent conductive material layer and the second transparent conductive material layer.

The above and other aspects of the invention will become better understood with regard to the following detailed description of the non-limiting embodiment (s). The following description is made with reference to the accompanying drawings.

### BRIEF DESCRIPTION OF THE DRAWINGS

FIG. 1A is a simple top view of a display panel according to the first embodiment of the present disclosure.

FIG. 1B is a partial enlargement of the circled area of FIG. 1A.

FIG. 1C is a cross-sectional view of a display panel along the cross-sectional line 1C-1C of FIG. 1B according to the first embodiment of the present disclosure.

FIG. 2A-FIG. 2F show processing steps for manufacturing a transistor array substrate of a display panel according to the first embodiment of the present disclosure.

FIG. 3 is a cross-sectional view of another substrate of a display panel according to the first embodiment of the present disclosure.

FIG. 4 is a cross-sectional view of a substrate of a display panel according to the second embodiment of the present disclosure.

FIG. 5 is a cross-sectional view of another substrate of a display panel according to the second embodiment of the present disclosure.

### DETAILED DESCRIPTION OF THE INVENTION

A display panel is provided in an embodiment of the present disclosure. According to the special structural design of the transistor array substrate of the display panel, the lateral surfaces of the conductive lines (formed of such as copper) of the transistor array substrate are covered with a transparent conductive material. The manufactured conductive lines (such as data lines) can avoid oxidation of the copper. Moreover, in each pixel region, the electrodes (such as a source electrode and a drain electrode) are composed of the transparent conductive materials, such that copper will not diffuse into the active layer and change the electrical properties of the display panel. Several embodiments of the present disclosure are disclosed below with reference to accompanying drawings. The embodiments of the present disclosure can be applied to a display panel whose transistor array substrate can have different implementations, such as an LCD panel with a back channel etch-type (BCE-type) TFT array substrate or an etch stop-type TFT array substrate. It should be noted that the structures and contents disclosed in the embodiments are for exemplary and explanatory purposes only. The present disclosure does not illustrate all possible embodiments, and anyone skilled in the technology field of the invention will be able to make suitable modifications or changes based on the specification disclosed below to meet actual needs without breaching the spirit of the invention. The present disclosure is applicable to other implementations not disclosed in the specification. In addition, the drawings are simplified such that the content of the embodiments can be clearly described, and the shapes, sizes and scales of elements are schematically shown in the drawings for explanatory and exemplary purposes only, not for limiting the scope of protection of the present disclosure.

Besides, the ordinal numbers, such as “the first”, “the second”, and “the third”, are used in the specification and the claims for modifying claim elements only, neither implying nor indicating that the claim elements have any previous ordinal numbers. The ordinal numbers do not indicate the sequence between one claim element and another claim element or the sequence in the manufacturing method. The ordinal numbers are used for clearly differentiating two claim elements having the same designation.

### First Embodiment

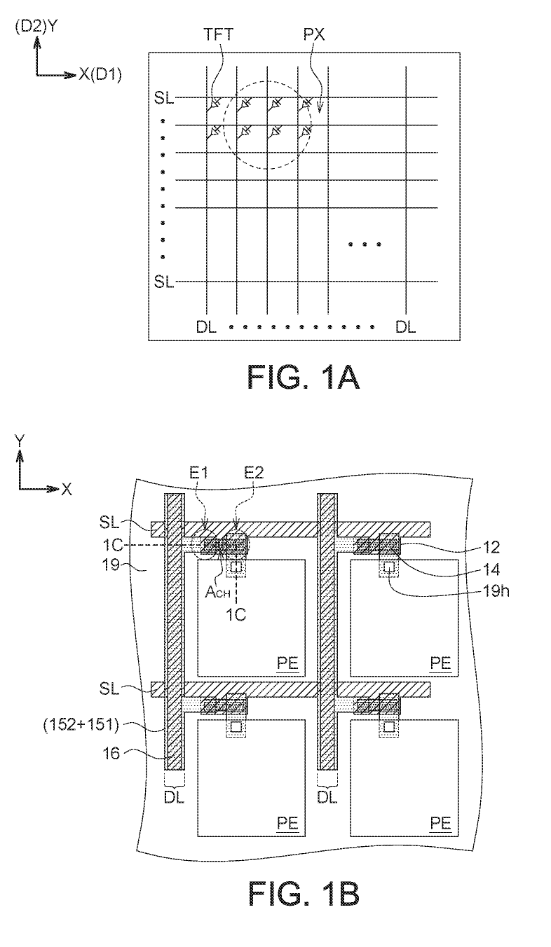

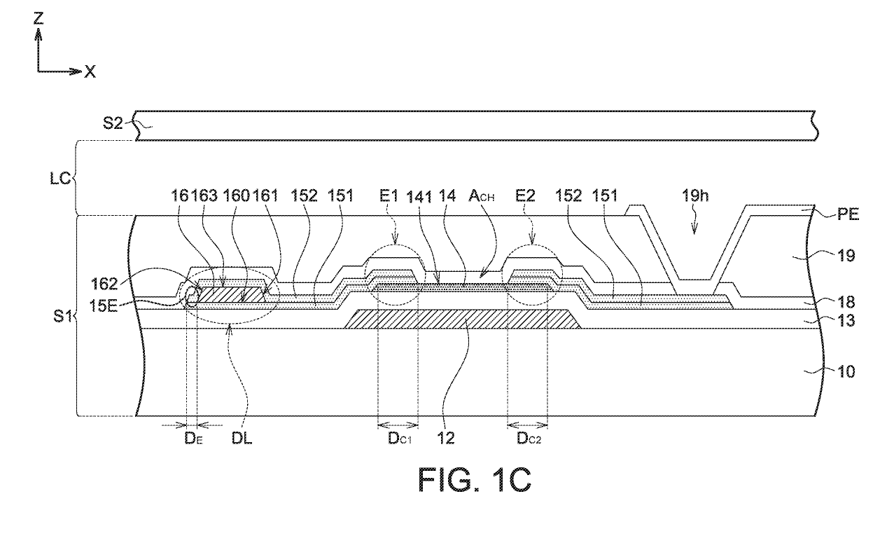

The first embodiment is exemplified by a display panel with a back channel etch type (BCE-type) TFT array substrate. Please refer to FIG. 1A-FIG. 1C. FIG. 1A is a simple top view of a display panel according to the first embodiment of the present disclosure. FIG. 1B is a partial enlargement of the circled area of FIG. 1A. FIG. 1C is a cross-sectional view of a display panel along the cross-sectional line 1C-1C of FIG. 1B according to the first embodiment of the present disclosure.

As indicated in FIG. 1A and FIG. 1B, the display panel of the present embodiment includes an array substrate. The array substrate includes a plurality of first conductive lines, such as the scan lines SL, and a plurality of second conductive lines, such as the data lines DL, intersected with the first conductive lines to define a plurality of pixel regions PX on an array, wherein the first conductive lines (such as the scan lines SL) extend along a first direction D1 (that is, the X direction), and the second conductive lines, such as the data lines DL, extend along a second direction D2 (that is, the Y direction). Each pixel region PX includes at least one switch element, such as a thin-film transistor, independently controlling an affiliated pixel region PX.

As shown in FIG. 1C, the display panel includes a first substrate S1, a second substrate S2 disposed opposite to the first substrate S1, and a display medium layer disposed between the first substrate S1 and the second substrate S2. In the present embodiment, the first substrate S1, the second substrate S2 and the display medium layer can be realized by such as a transistor array substrate, a color filter substrate, and a liquid crystal layer LC, respectively. In the first embodiment, the first substrate S1 is exemplified by a structure in which a source electrode and a drain electrode are directly formed on a semiconductor layer (i.e. an active layer) and located on two sides of a channel region A_{CH}.

As indicated in FIG. 1C, one of the transistors disposed over a base plate 10 includes a gate electrode 12 (formed of copper or other suitable metal material). A first insulating layer 13 is disposed over the gate electrode 12, and an active layer 14 (such as a semiconductor layer) is disposed over the first insulating layer 13. The active layer 14 includes a channel region A_{CH}. The first electrode E1 and the second electrode E2 are disposed over the active layer 14, and the channel region A_{CH} is disposed between the first electrode E1 and the second electrode E2. In an embodiment, the material of the active layer 14 includes an oxide semiconductor (or a metal oxide semiconductor), such as zinc oxide (ZnO), indium zinc oxide (IZO), or indium gallium zinc oxide (IGZO). Besides, the transistor further includes a second insulating layer 18 covering the first electrode E1 and the second electrode E2, and a third insulating layer 19 disposed over the second insulating layer 18. The second insulating layer 18 and the third insulating layer 19 can be composed of single-layer film, double-layer or multi-layer films. For example, in the present embodiment, the second insulating layer 18 includes a silicon oxide film and a silicon nitride film. In each pixel region, the pixel electrode PE (formed of such as ITO) is electrically connected to the second electrode E2 through a contact hole 19h in the second insulating layer 18 and the third insulating layer 19 as shown in FIG. 1B and FIG. 1C.

The structure of the present disclosure is not limited to that illustrated in FIG. 1A-1C. For example, the first direction D1 and the second direction D2 are perpendicular to each other in the first embodiment, but the first direction D1 and the second direction D2 may form an angle ranging from 75 degrees to 90 degrees n other embodiment. Moreover, other elements (such as less relevant elements) of the second substrate S2 are omitted from the drawings for more clearly illustrating the present disclosure.

According to the present disclosure, in the display region of the display panel, the first electrode E1 (such as a source electrode) and the second electrode E2 (such as a drain electrode) are formed of a transparent conductive material. The conductive line, such as a data line DL, connected to one of the two electrodes is composed of a metal layer and double layers of transparent conductive material. In the first embodiment, the first electrode E1 (such as a source electrode) is composed of double layers of transparent conductive material including a first transparent conductive material layer 151 formed on the active layer 14 and a second transparent conductive material layer 152 formed on the first transparent conductive material layer 151. The second conductive line, such as the data line DL, connected to the first electrode E1 includes a third transparent conductive material layer, a metal layer 16 and a fourth transparent conductive material layer, wherein the metal layer 16 is disposed between the third transparent conductive material layer and the fourth transparent conductive material layer. In an embodiment, in each pixel region, the first transparent conductive material layer 151 and the second transparent conductive material layer 152 of the first electrode E1 extend to the corresponding metal layer 16 of the second conductive line and encapsulate the metal layer 16 to form the third transparent conductive material layer and the fourth transparent conductive material layer, respectively. As indicated in FIG. 1C, the second conductive line, such as the data line DL, includes a metal layer 16 disposed between the first transparent conductive material layer 151 and the second transparent conductive material layer 152. Similarly, the second electrode E2 (such as drain electrode) is composed of the first transparent conductive material layer 151 formed on the active layer 14 and the second transparent conductive material layer 152 formed on the first transparent conductive material layer 151. Although the first electrode E1 and the second electrode E2 both include the first transparent conductive material layer 151 and the second transparent conductive material layer 152 in the present embodiment, the first electrode E1 and the second electrode E2 are not in a physical connection.

As shown in FIG. 1C, in each pixel region, the first transparent conductive material layer 151 and the second transparent conductive material layer 152 of the first electrode E1 extend to the corresponding metal layer 16 and encapsulate or cover the metal layer 16 to form the second conductive line, such as a data line DL. The metal layer 16 is formed on the first transparent conductive material layer 151 and has a bottom surface 160 directly contacting the first transparent conductive material layer 151. The second transparent conductive material layer 152 is formed on the metal layer 16 and directly contacts and covers the lateral surfaces 161 and 162 and the top surface 163 of the metal layer 16.

In an embodiment, the first transparent conductive material layer 151 and the second transparent conductive material layer 152 comprises metal oxide, and can be realized by an IZO layer or an ITO layer, but not limited to the materials mentioned above. The first transparent conductive material layer 151 and the second transparent conductive material layer 152 can be formed of the same or different transparent conductive materials. In an embodiment, the metal layer 16 can be realized by a copper layer. Thus, in each pixel region, the source electrode and the drain electrode are consisting of a transparent conductive material (such as IZO), that is, no metal material layer is disposed over the active layer 14, but the data line DL is formed of copper encapsulated with the transparent conductive material (such as IZO/Cu/IZO).

Moreover, at the data line DL, a lateral surface 161 of the metal layer 16 is adjacent to the active layer 14, and a lateral surface 162 of the metal layer 16, opposite to the lateral surface 161, is farther away from the active layer 14. The first transparent conductive material layer 151 and the second transparent conductive material layer 152 overlap on the lateral surface 162 of the metal layer 16 and form an extension portion 15E having an extension width D_{E}. In an embodiment, the extension width D_{E} is about 0.1 μm-4 μm. Anyone skilled in related art would understand that the values and ranges exemplified herein are for reference and explanatory purposes only, and can be properly adjusted to fit production specifications. Therefore, the values and ranges are not for limiting the scope of protection of the present disclosure.

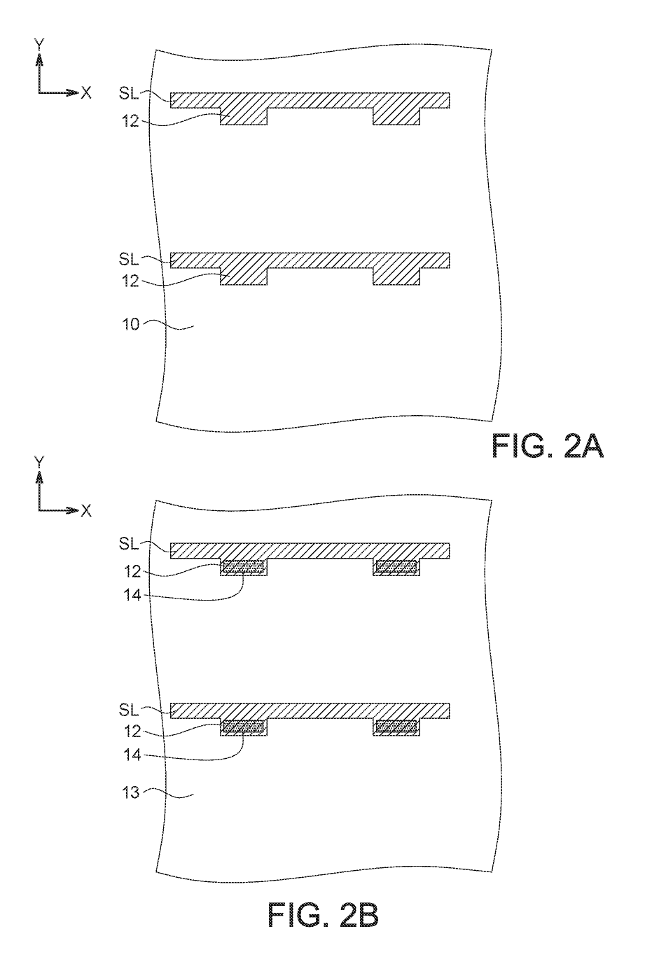

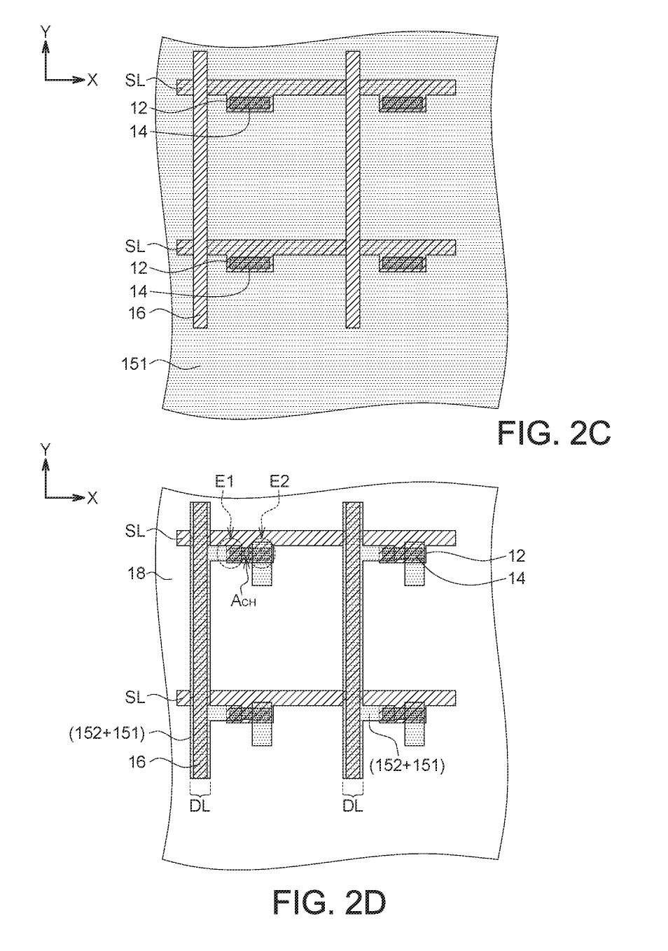

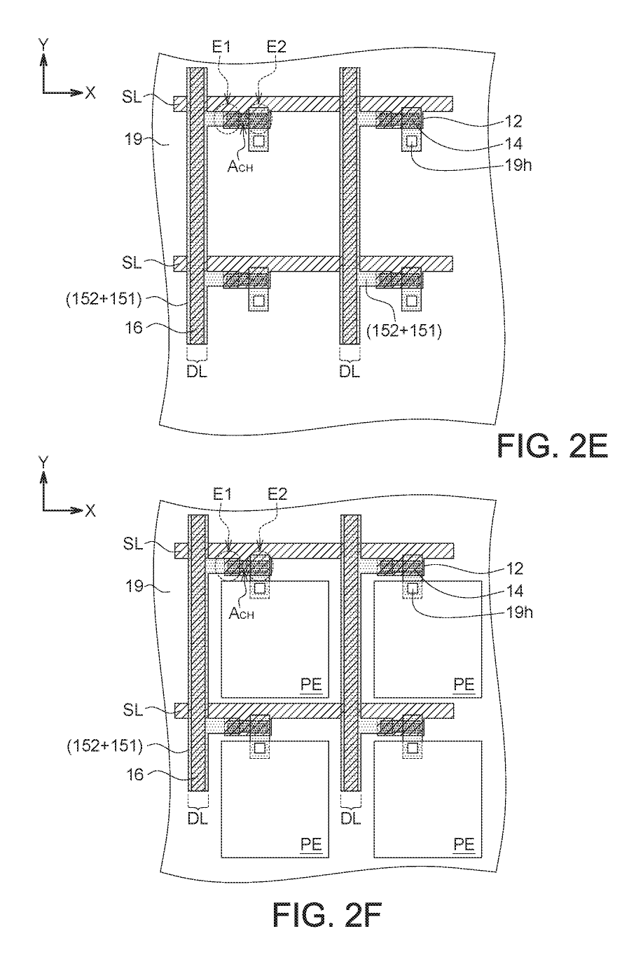

FIG. 2A-FIG. 2F show processing steps for manufacturing a transistor array substrate of a display panel according to the first embodiment of the present disclosure. Please refer to FIG. 1A-FIG. 1C and FIG. 2A-FIG. 2F at the same time. The elements identical to FIG. 2A-FIG. 2F and FIG. 1A-FIG. 1C retain the same numeric designations to simplify the descriptions of the elements. As indicated in FIG. 2A, a base plate 10 is provided, and a first metal layer is formed on the base plate 10, and the first metal layer is patterned to define a plurality of mutually parallel first conductive lines, such as scan lines SL, and a gate electrode 12, wherein the scan lines SL extend along a first direction D1 (the X direction). The first metal layer can also be referred as gate metal wires which can be formed of copper or other metal material having low resistance.

As indicated in FIG. 2B, a first insulating layer 13 is formed on the base plate and covers the gate electrode 12, wherein the first insulating layer 13 is formed on the entire surface and used as a gate insulating layer. Then, an oxide semiconductor layer is formed and is further processed with a developing and etching process to form a plurality of active layers 14 on the first insulating layer 13. The oxide semiconductor layer can be formed of an ion-bonded semiconductor material, such as zinc oxide (ZnO), indium zinc oxide (IZO), indium gallium zinc oxide (IGZO) or other suitable materials.

Then, the first transparent conductive material layer 151 (such as IZO) is formed on the entire surface and covers the first insulating layer and the active layer 14; then, a metal layer (such as copper) is formed and a metal trace area is defined. That is, metal is removed from the channel region, the pixel region and other regions not requiring the metal. Accordingly, the metal layers 16 forming conductive traces are defined, and the first transparent conductive material layer 151 is completely retained as shown in FIG. 2C.

Afterward, the second transparent conductive material layer 152 (such as IZO) completely coves the first transparent conductive material layer 151. The second transparent conductive material layer 152 further covers the metal layers 16. Then, the first transparent conductive material layer 151 and the second transparent conductive material layer 152 are patterned at the same time to define a metal trace area. A source area and a drain area of a thin-film transistor, the metal layer 16, and the lateral surfaces 161 and 162 of the metal layer 16 are also covered by the second transparent conductive material layer 152 as indicated in FIG. 2D. Furthermore, in this pattern-defining step, the channel region A_{CH} in each pixel region exposes a top surface of the corresponding active layer 14. Thus, the second conductive line, such as the data lines DL as mentioned above (FIG. 1C) includes the first transparent conductive material layer 151 and the second transparent conductive material layer 152 covering the metal layer 16 (such as IZO/Cu/IZO). Viewing from the top view, the area of the transparent conductive layer (such as second transparent conductive material layer 152) is larger than that of the metal layer 16 (such as copper wires).

Then, a second insulating layer 18 and a third insulating layer 19 (used as an insulating passivation layer) are formed on the second transparent conductive material layer 152, and a contact hole is defined. For example, a contact hole 19h penetrates the third insulating layer 19 and the second insulating layer 18 to expose the top surface of the second transparent conductive material layer 152 of the second electrode E2, as indicated in FIG. 2E.

A pixel electrode layer (formed of such as ITO) is formed and patterned to form a pixel electrode PE in each pixel region, as shown in FIG. 2F. The pixel electrode PE is electrically connected to a second electrode E2 through the contact hole 19h (such as contacting the second transparent conductive material layer 152).

After manufacturing the first substrate S1, the first substrate S1 is further assembled with the second substrate S2 (FIG. 1C), and a display medium layer (such as the liquid crystal layer LC of FIG. 1C) is disposed between the first substrate S1 and the second substrate S2. Thus, the manufacture of the display panel is completed.

As indicated in FIG. 1C, a contact portion between the first transparent conductive material layer 151 of the first electrode E1 and the top surface 141 of the active layer 14 has a first contact width D_{C1}, a contact portion between the first transparent conductive material layer 151 of the second electrode E2 and the top surface 141 of the active layer 14 has a second contact width D_{C2}, and the first contact width D_{C1} can be identical to the second contact width D_{C2}.

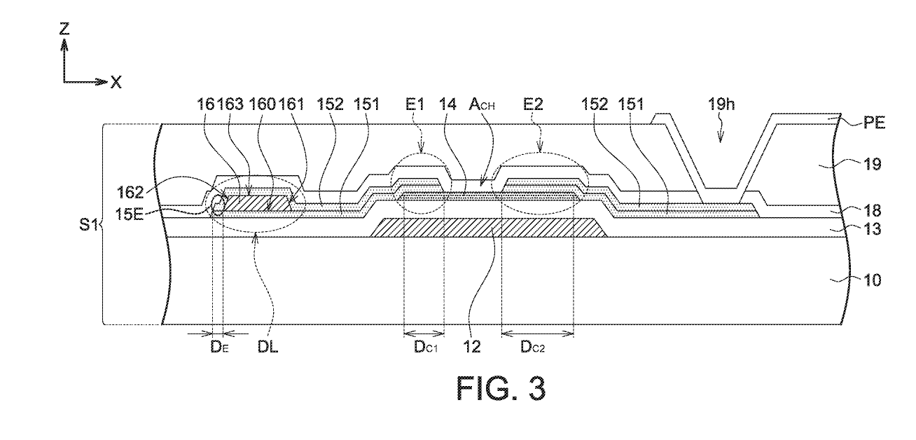

However, the present disclosure is not limited thereto, and the contact widths D_{C1} and D_{C2} on the two sides of the channel region A_{CH} can be different from each other. FIG. 3 is a cross-sectional view of another substrate of a display panel according to the first embodiment of the present disclosure. In another implementation, the first contact width D_{C1} is different from the second contact width D_{C2}. Under such design, the gate/pixel electrode has a larger capacitance (Cg pixel) and the gate/drain has a smaller capacitance (Cgd). The gate/drain with a smaller capacitance can cause the capacitance of the data lines (Cdata) to decrease.

### Second Embodiment

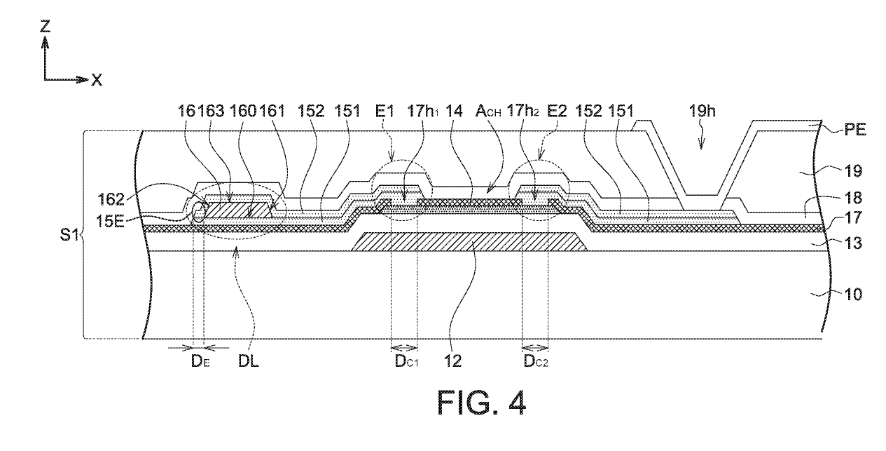

FIG. 4 is a cross-sectional view of a substrate of a display panel according to the second embodiment of the present disclosure. The second embodiment is exemplified by a display panel having an etch stop-type TFT array substrate. The elements identical to FIG. 4 and FIG. 1C retain the same numeric designations to simplify the descriptions of the elements. For the identical elements of the second embodiment and the first embodiment, details of their structures, materials and disposition of the elements are already disclosed in the first embodiment, and are not repeated herein.

The second embodiment is different from the first embodiment in that: in each pixel region, the transistor further includes an etch stop layer 17 disposed between the active layer 14 and the first electrode E1 and the second electrode E2. The etch stop layer 17 has a first opening 17h₁ and a second opening 17h₂ on corresponding positions of the first electrode E1 and the second electrode E2, respectively. In the second embodiment, the first electrode E1 contacts the active layer 14 through the first opening 17h₁ and the second electrode E2 contacts the active layer 14 through the second opening 17h₂. The widths of the two openings determine the contact width by which the first transparent conductive material layer 151 contacts the top surface 141 of the active layer 14. That is, a contact portion between the first transparent conductive material layer 151 of the first electrode E1 and the top surface 141 of the active layer 14 has a first contact width D_{C1} (corresponding to the size of the first opening 17h₁); a contact portion between the first transparent conductive material layer 151 of the second electrode E2 and the top surface 141 of the active layer 14 has a second contact width D_{C2} (corresponding to the size of the second opening 17h₂). Moreover, the thickness of the active layer 14 corresponding to the first opening 17h₁ and the second opening 17h₂ can be smaller than the thickness of the channel region A_{CH}.

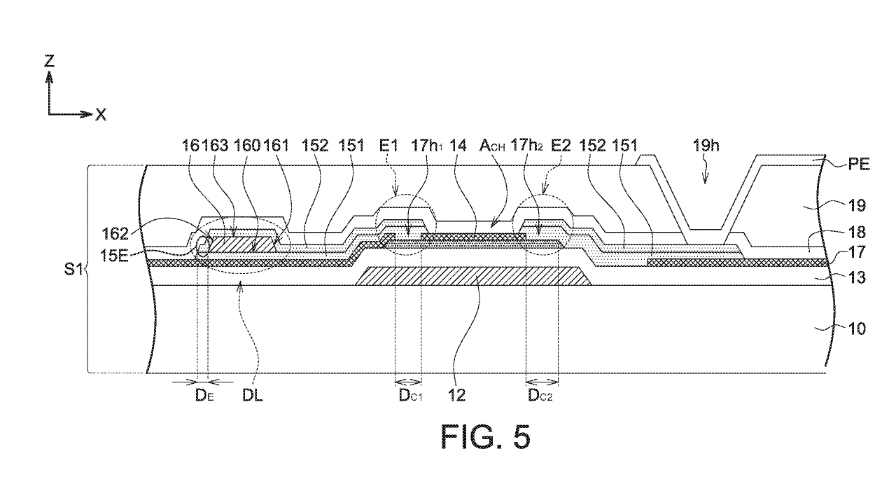

As indicated in FIG. 4, the size of the first opening 17h₁ can be the same as that of the second opening 17h₂. That is, the first contact width D_{C1} can be equal to the second contact width D_{C2}. However, the present disclosure is not limited thereto, and the contact widths D_{C1} and D_{C2} on the two sides of the channel region A_{CH} can be different from each other. FIG. 5 is a cross-sectional view of another substrate of a display panel according to the second embodiment of the present disclosure. Like the implementation as indicated in FIG. 3 of the first embodiment, the first opening 17h₁ is different from the second opening 17h₂ in the second embodiment. That is, the first contact width D_{C1} is different from the second contact width D_{C2}. As indicated in FIG. 5, the first opening 17h₁ is smaller than the second opening 17h₂. Under such design, the gate/pixel electrode has a larger capacitance (Cg pixel) and the gate/drain has a smaller capacitance (Cgd). The gate/drain with a smaller capacitance can cause the capacitance of the data lines (Cdata) to decrease.

The structure and the manufacturing process (such as the bottom gate, five mask manufacturing process and the manufactured structure) are disclosed above for describing some embodiments of the present disclosure, not for limiting the scope of the present disclosure. Other embodiments with different implementations of the structure are still within the scope of the present disclosure. Examples of the implementations of structure include different types of switch such as TFT. Based on the process requirement, the edges of two transparent conductive material layers used as the source/drain electrode can be even or have level difference. The contact widths of the contact portions by which the first transparent conductive material layer of the two electrodes contacts the active layer, the position of the contact hole used for connecting the pixel electrode, and the positions and sizes of the openings at which the etch stop layer corresponds to the electrodes can be adjusted to meet the design requirements. Anyone ordinary skilled in the technology field of the present disclosure will understand that relevant structures and manufacturing process of the present disclosure can be adjusted or modified to meet the product requirements. However, after adjustment or modification is done, structures and manufacturing process of the present disclosure still need to comply with the operational specifications of the products (such as charging performance and capacitive load of the transistors still need to comply with ordinary product requirements) and maintain good electrical properties of the display panel.

According to the structural design of the transistor array substrate of the display panel of the present disclosure, the wires, such as copper layer, are encapsulated or covered by the transparent conductive material. For example, the top surface and the bottom surface of the metal layer 16 are respectively covered with the second transparent conductive material layer 152 and the first transparent conductive material layer 151, and the second transparent conductive material layer 152 also covers the lateral surfaces 161 and 162 of the metal layer 16. The manufactured conductive lines, such as the data lines DL (ex: each data line expressed by the material layers in an order such as IZO/Cu/IZO), can avoid oxidation of the copper surface in subsequent processes (for example, surface treatment using N₂O plasma applied on the active layer 14 after defining the electrode but before depositing the passivation layer). Moreover, in each pixel region, the first electrode E1 (such as a source electrode) and the second electrode E2 (such as a drain electrode) are composed of a transparent conductive material (formed of such as IZO), that is, no metal material such as copper is formed on the active layer 14, such that copper will not diffuse into the active layer 14 (ex: a semiconductor material) and change the electrical properties of the display panel. Furthermore, the manufacturing process for the substrate as disclosed in the embodiment is simple and time saving, and is suitable for mass production.

While the invention has been described by way of example and in terms of the above embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A display panel, comprising:
a first substrate, comprising a plurality of first conductive lines, a plurality of second conductive lines intersected with the first conductive lines, and a plurality of transistors disposed over a base plate, wherein the first conductive lines, the second conductive lines and the transistors together define a plurality of pixel regions, the first conductive lines extend along a first direction and the second conductive lines extend along a second direction, and at least one of the plurality of transistors in the plurality of pixel regions comprises:
a gate electrode disposed over the base plate;
a first insulating layer disposed over the gate electrode;
an active layer disposed over the first insulating layer and comprising a channel region;
a first electrode and a second electrode disposed over the active layer and electrically connected to the active layer, wherein the first electrode and the second electrode are located on two sides of the channel region, and the first electrode comprises a first transparent conductive material layer disposed over the active layer and a second transparent conductive material layer disposed over the first transparent conductive material layer,
wherein at least one of the second conductive lines is connected to the first electrode, the at least one second conductive line comprises a third transparent conductive material layer, a metal layer and a fourth transparent conductive material layer, and the metal layer is disposed between the third transparent conductive material layer and the fourth transparent conductive material layer;
a second substrate, disposed opposite to the first substrate; and
a display medium layer disposed between the first substrate and the second substrate.

2. The display panel according to claim 1, wherein the first transparent conductive material layer and the second transparent conductive material layer of the first electrode extend to the metal layer of the corresponding second conductive line and encapsulate the metal layer to form the third transparent conductive material layer and the fourth transparent conductive material layer respectively.

3. The display panel according to claim 2, wherein the metal layer is disposed over the first transparent conductive material layer, and the second transparent conductive material layer is disposed over lateral surfaces and a top surface of the metal layer.

4. The display panel according to claim 3, wherein the first transparent conductive material layer and the second transparent conductive material layer overlap on the lateral surface of the metal layer farther away from the active layer and form an extension portion having an extension width of about 0.1 μm-4 μm.

5. The display panel according to claim 1, wherein the second electrode comprises the first transparent conductive material layer and the second transparent conductive material layer.

6. The display panel according to claim 1, wherein a contact portion between the first electrode and a top surface of the active layer has a first contact width, and a contact portion between the second electrode and the top surface of the active layer has a second contact width, and the first contact width is different from the second contact width.

7. The display panel according to claim 6, wherein the first contact width is smaller than the second contact width.

8. The display panel according to claim 1, wherein the first transparent conductive material layer and the second transparent conductive material layer include metal oxide, and the active layer includes metal oxide semiconductor.

9. The display panel according to claim 1, wherein the at least one transistor further comprises an etch stop layer disposed between the active layer and the first electrode and the second electrode, the etch stop layer has a first opening and a second opening, and the first electrode and the second electrode contact the active layer through the first opening and the second opening, respectively.

10. A manufacturing method of a display panel, comprising:
forming a first substrate, comprising:
forming a first metal layer on a base plate,
patterning the first metal layer to form a plurality of first conductive lines and a plurality of gate electrodes, wherein the first conductive lines extend along the a first direction and connect corresponding gate electrodes;
forming a first insulating layer to cover the gate electrodes and the first conductive lines;
forming a plurality of active layers on the first insulating layer;
forming a first transparent conductive material layer on the first insulating layer;
forming a plurality of metal layers on the first transparent conductive material layer;
forming a second transparent conductive material layer on the metal layers and the first transparent conductive material layer;
patterning the first transparent conductive material layer and the second transparent conductive material layer to form a plurality of second conductive lines extending along a second direction, a plurality of first electrodes, and a plurality of second electrodes on the base plate, wherein each of the plurality of second conductive lines comprises a first transparent conductive layer formed of the first transparent conductive material layer, the metal layer, and a second transparent conductive layer formed of the second transparent conductive material layer, and the plurality of second conductive lines are intersected with the plurality of first conductive lines to define a plurality of pixel regions;
wherein, in each of the plurality of pixel regions, the first electrode and the second electrode are disposed over the active layer, a channel region is disposed between the first electrode and the second electrode, and the first electrode is consisting of the first transparent conductive material layer and the second transparent conductive material layer,
providing a second substrate and assembling the e second substrate with the first substrate; and
providing a display medium layer between the first substrate and the second substrate.
